(19) United States
(12) Patent Application Publication
(10) Pub. No.: US 2008/0078442 A1
(43) Pub. Date: Apr. 3, 2008

(54) ELECTRIC WIRE FOR SOLAR CELL HAVING BENT PORTION

(75) Inventor: Sang-Hoon LIM, Seo-gu (KR)

Correspondence Address: OBLON, SPIVAK, MCCLELLAND MAIER & NEUSTADT, P.C., 1940 DUKE STREET, ALEXANDRIA, VA, 22314, US

(73) Assignee: KOREA INSTITUTE OF ENERGY RESEARCH, Yuseong-gu (KR)

(21) Appl. No.: 11/742,762

(22) Filed: May 1, 2007

(30) Foreign Application Priority Data
Oct. 2, 2006 (KR) 10-2006-0097333

(51) Int. Cl. H01L 31/02

(52) U.S. Cl. 136/256

(57) ABSTRACT

Disclosed herein is an electric wire for solar cells having a bent portion, which is attached to a tape having an adhesive surface such that the electric wire for carrying electricity produced from the solar cells can be installed to a desired place without requiring any outwardly protruding fixing structure, thereby achieving a simplified installation thereof and preventing a risk of damage to other peripheral electronic devices or people. The electric wire constitutes a part of a power supply system comprising solar cells to convert sunlight into electricity and a charging battery to receive and store the electricity from the solar cells, and is used to carry the electricity from the charging battery to an electronic device. The electric wire is bent at least one time by a predetermined angle, and attached to the adhesive surface of the tape.

### BACKGROUND OF THE INVENTION

1. Field of the Invention

The present invention relates to an electric wire for solar cells having a bent portion, and more particularly, to a solar cell electric wire having a bent portion, which is attached to a tape having an adhesive surface such that the electric wire for carrying electricity produced from the solar cells can be installed to a desired place without requiring any outwardly protruding fixing structure, thereby achieving a simplified installation thereof and preventing a risk of damage to other peripheral electronic devices or people.

More particularly, the present invention relates to an electric wire for solar cells having a bent portion, which can be easily installed to certain bent portions of, for example, windows and corners.

2. Description of the Related Art

Generally, power supply sources using solar cells are installed in places having a difficulty in the supply of electricity via power lines, and are usable in emergency display panels and emergency power supply sources. In another use example regarding energy saving, the solar cells may be attached to windows, etc. to produce electricity from sunlight, such that the electricity produced by the solar cells can be used as electric energy of a variety of electronic devices, for example, an illuminator of a picture frame or wall-mounted aquarium.

A conventional power supply device using solar cells is configured such that, if solar cells convert sunlight into electricity, the electricity is charged into a battery, so as to be used as electric energy for the operation of a variety of electronic devices.

FIG. 7 is a schematic view illustrating the installation example of a conventional electric wire used to carry electricity produced from solar cells. As shown, a plurality of solar cells 100 to convert sunlight into electricity are attached to a window 200.

Provided at a side of the solar cells 100 is a transformer 400. The transformer 400 is used to change the electric characteristics of the electricity, produced from the solar cells 100 using sunlight, and to charge the electricity into a charging battery 300.

An electric wire 500 is used to connect the solar cells 100 with the transformer 400 and to connect the transformer 400 with the charging battery 300.

The charging battery 300 may be electrically connected to a variety of electronic devices. For example, as shown, the charging battery 300 is electrically connected to an illuminator 700 via the electric wire 500, to supply the electricity charged in the battery 300 to the illuminator 700 of a wall-mounted picture frame 600.

Here, it is noted that the charging battery 300 and the illuminator 700 are spaced apart from each other by a predetermined distance, therefore it is necessary to secure the electric wire 500 extending between the charging battery 300 and the illuminator 700 to a fixed position on the wall. Generally, the electric wire 500 has been fixed by use of fixing means 800, such as nails, holding pins or molds, or the like.

However, when the electric wire, used to carry electricity produced from solar cells, is fixed to the wall by use of fixing means, there is a problem in that electricity flowing through the electric wire may have a significantly increased resistance despite that electricity produced from solar cells originally has a relatively low current intensity without a risk of electric shock.

Moreover, when the electric wire between the charging battery and the illuminator is fixed to the wall by use of nails or holding pins, the nails or holding pins are inevitably protruded from the wall, thus having a possibility of scratches or damage to other peripheral electronic devices or people.

To solve the above described problems, the applicant of the present invention developed and filed an electric wire that is designed to be attached to an adhesive surface of a tape.

The electric wire, developed by the applicant of the present invention, however, has a problem in that it is allowed to be installed only linearly. If it is attempted to bend the electric wire to conform to any bent installation places, it may cause unwanted distortion or tear of the tape, thus making it impossible to safely and firmly secure the electric wire at a fixed position.

### SUMMARY OF THE INVENTION

Therefore, the present invention has been made in view of the above problems, and it is an object of the present invention to provide an electric wire for solar cells having a bent portion, which can be easily fixed to a building structure, such as a wall or post, without using separate fixing means, and can achieve a bent wiring shape.

In accordance with one aspect of the present invention, the above and other objects can be accomplished by the provision of an electric wire for solar cells having a bent portion, the electric wire constituting a part of a power supply system comprising solar cells to convert sunlight into electricity and a charging battery to receive and store the electricity from the solar cells, the electric wire being used to carry the electricity from the charging battery to an electronic device, wherein the electric wire is bent at least one time by a predetermined angle, and attached to an adhesive surface of a tape.

The tape may have a single adhesive surface or both adhesive surfaces. In preparation of the tape, a plurality of tapes may be arranged on a roll of sheet. In this case, a plurality of bent electric wires can be provided together at a predetermined interval.

As a result of providing the adhesive surface or adhesive surfaces at an inner surface or both surfaces of the tape, the electric wire for solar cells having a bent portion according to the present invention has advantages of a simplified installation thereof without requiring any outwardly protruding fixing structure, thus having no risk of deterioration of wire's outer appearance and being available to certain places requiring for the bent electric wire.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a perspective view illustrating an electric wire for solar cells having a bent portion according to one embodiment of the present invention;

FIG. 2 is a perspective view illustrating an electric wire for solar cells having a bent portion according to another embodiment of the present invention;

FIG. 3 is a perspective view illustrating an electric wire for solar cells having a bent portion according to yet another embodiment of the present invention;

FIG. 4 is a perspective view illustrating a roll stock of an electric wire for solar cells having a bent portion according to the present invention;

FIG. 5 is an enlarged perspective view illustrating a part of the roll stock shown in FIG. 4;

FIG. 6 is a schematic view illustrating the installation example of an electric wire for solar cells having a bent portion according to the present invention; and

FIG. 7 is a schematic view illustrating the installation example of a conventional electric wire used to carry power from solar cells.

### DETAILED DESCRIPTION OF THE PREFERRED EMBODIMENTS

The present invention will be clearly understood by reading following preferred embodiments with reference to the accompanying drawings. Hereinafter, the preferred embodiments will be described in detail to assist those skilled in the art to easily understood and realize the present invention.

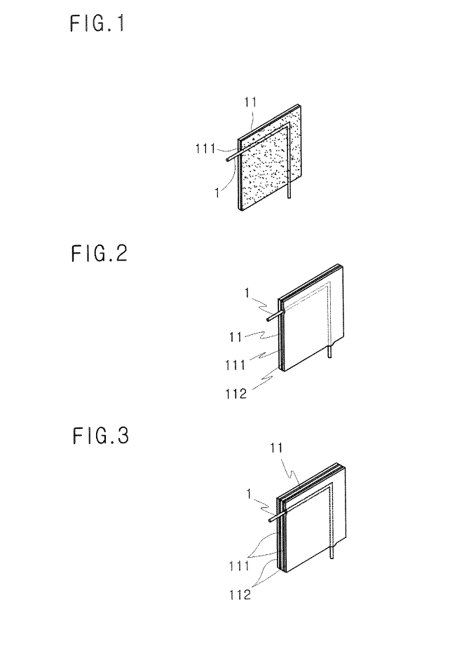

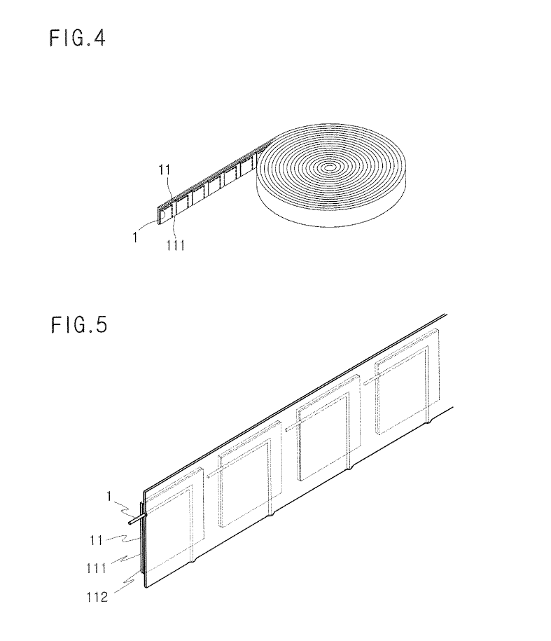

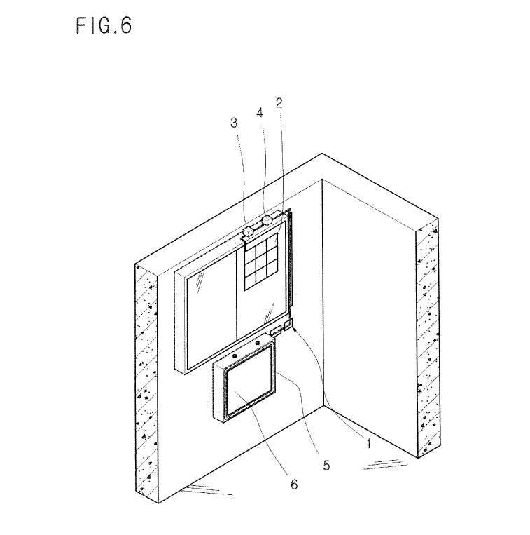

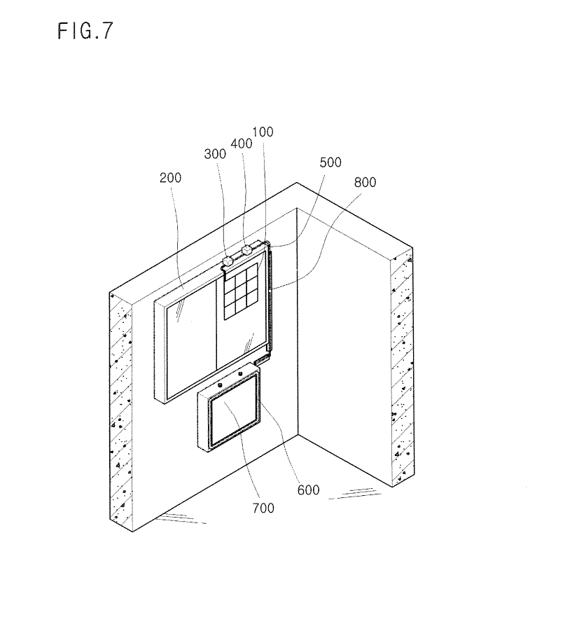

FIGS. 1 to 3 are perspective views illustrating an electric wire for solar cells having a bent portion according to different embodiments of the present invention. FIG. 4 is a perspective view illustrating a roll stock of the electric wire, and FIG. 5 is an enlarged perspective view illustrating a part of the roll stock shown in FIG. 4. Also, FIG. 6 is a schematic view illustrating the installation example of the electric wire.

As shown, the electric wire 1 for solar cells according to the present invention is bent at least one time by a predetermined angle, and the resulting electric wire having at least one bent portion is attached to a surface of a tape 11.

The electric wire 1 may be a one-strand wire as shown, or may be comprised of a plurality of strands arranged parallel to each other. The electric wire 1 is bent to have a right-angle bent portion, or to have an acute-angle or obtuse-angle bent portion. The electric wire 1 is adhesively fixed to the surface of the tape 11.

The surface of the tape 11, to which the electric wire 1 is attached, is an adhesive surface 111 coated with an adhesive. The adhesive surface 111 of the tape 11 is able to be attached to any building structure, for example, a wall or post. Accordingly, the electric wire 1 is able to be attached to the wall or post by use of the tape 11.

In another embodiment of the present invention, a release sheet 112 may be further provided on the adhesive surface 111 of the tape 11, onto which the electric wire 1 was previously attached. The release sheet 112 serves to cover and protect the adhesive surface 111, so as to prevent the adhesive surface 111 from being attached to any unwanted place.

A surface of the release sheet 112, facing the adhesive surface 111 of the tape 11, is coated with a silicone resin emersion, to guarantee the release sheet 112 to be easily separated from the adhesive surface 111 if necessary.

The electric wire 1, as shown in FIGS. 1 to 3, is arranged on the tape 11 such that both ends of the electric wire 1 are protruded out of the tape 11, but the most part of the electric wire 1 is extended on the adhesive surface 111 and covered with the release sheet 112. Accordingly, the electric wire 1 can be protected by the release sheet 112.

As shown in FIG. 3, in a further embodiment of the present invention, both surfaces of the tape 11 may constitute adhesive surfaces 111. Providing the tape 11 with both the adhesive surfaces 111 enables one or more electric wires to be laminated one above another, or any other articles, for example, a desired decoration, to be attached to the outer surface of the tape 11.

The release sheet 112 may be a long-length sheet suitable to form a roll of sheet.

Assuming that the release sheet 112 has a long length, as shown in FIGS. 4 and 5, after electric wires 1 are attached, respectively, to a plurality of tapes 11, the tapes 11 can be arranged on the release sheet 112 at a predetermined interval. Then, if the release sheet 112 is rolled, the resulting roll of release sheet can guarantee the convenient storage and transport of the electric wires.

Hereinafter, a possible use example of the electric wire 1 for solar cells having the above described configuration will be described with reference to FIG. 6.

FIG. 6 schematically illustrates one use example of the electric wire for solar cells having a bent portion according to the present invention. As shown, an exemplary solar-cell power supply system comprises a plurality of solar cells 2, a transformer 3, a charging battery 4, a wall-mounted decorative article 5, an illuminator 6, and the electric wire 1 for solar cells having a bent portion.

Although the illustrated use example exemplifies that the electric wire for solar cells having a bent portion is adapted to carry electricity to the illuminator 6 of the wall-mounted decorative article 5, it will be appreciated that the electric wire is available in a variety of electronic devices without being limited to the above use example.

A more detailed description of the above use example is as follows.

The plurality of solar cells 2 are attached to a window, in order to convert sunlight into electricity. To preserve natural lighting through the window, preferably, the solar cells 2 may be made of a transparent material.

The transformer 3 is used to change the electric characteristics of the electricity, produced from the solar cells 2, so as to impart a predetermined current intensity to the resulting electricity. The charging battery 4 is used to store the electricity having passed through the transformer 3.

The electric wire 1 for solar cells having a bent portion is used to electrically connect the charging battery 4 to the illuminator 6, so as to supply the electricity stored in the charging battery 4 to the illuminator 6, for the operation of the illuminator 6.

Here, the electric wire 1 for solar cells having a bent portion is attached to the adhesive surface 111 of the tape 11 and thus, can achieve an easy installation thereof. In particular, the electric wire 1 can be conveniently attached to any bent places requiring the bending of the electric wire, and may be connected, at both ends thereof, to different electric wires.

Differently from the aforementioned conventional electric wire having a risk of damage caused by nails or holding pins that are used to secure the electric wire at a fixed position, the electric wire for solar cells having a bent portion according to the present invention can achieve a simplified safe installation thereof without requiring any outwardly protruding fixing structure because it is attached to the adhesive surface of the tape.

As apparent from the above description, the electric wire for solar cells having a bent portion according to the present invention has the following effects.

Firstly, as a result of attaching the electric wire, which is used to carry electricity produced from solar cells, to an adhesive surface of a tape, the electric wire of the present invention can achieve a simplified installation and consequently, increase a utility thereof to the maximum extent. In particular, when it is necessary to install the electric wire to any bent places, the electric wire according to the present invention can be installed easily and safely without a risk of distortion or tear of the tape that may be caused on the nature of the bent places. As a result, an easy wiring of the electric wire can be accomplished and there is no deterioration of the installed wire's external appearance.

Secondly, the electric wire for solar cells having a bent portion according to the present invention has no need for separate fixing means upon installation thereof. Accordingly, the electric wire has advantages of guaranteeing a simplified installation and a reduced risk of damage.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. An electric wire for solar cells having a bent portion, the electric wire constituting a part of a power supply system comprising solar cells to convert sunlight into electricity and a charging battery to receive and store the electricity from the solar cells, the electric wire being used to carry the electricity from the charging battery to an electronic device, wherein
the electric wire is bent at least one time by a predetermined angle, and attached to an adhesive surface of a tape.

2. The electric wire according to claim 1, wherein the electric wire is extended on the adhesive surface of the tape such that both ends of the wire are protruded from edges of the tape, and a release sheet is further provided on the adhesive surface of the tape to cover the electric wire while exposing both the ends of the wire to the outside.

3. The electric wire according to claim 2, wherein the release sheet takes the form of a roll of sheet, and a plurality of tapes, onto which electric wires are attached, respectively, are arranged on the release sheet at a predetermined interval.

4. The electric wire according to claim 3, wherein the adhesive surface of the tape is formed only at an inner surface of the tape where the electric wire is provided.

5. The electric wire according to claim 3, wherein the adhesive surface of the tape is formed at both surfaces of the tape.
